(19) United States
(12) Patent Application Publication
(10) Pub. No.: US 2006/0032616 A1
(43) Pub. Date: Feb. 16, 2006

(54) Compound heat-dissipating device

(75) Inventor: Hsiang-Hsi Yang, Kao Hsiung City (TW)

Correspondence Address: TROXELL LAW OFFICE PLLC;SUITE 1404, 5205 LEESBURG PIKE, FALLS CHURCH, VA, 22041, US

(73) Assignee: GIGA-BYTE TECHNOLOGY CO., LTD.

(21) Appl. No.: 10/915,544

(22) Filed: Aug. 11, 2004

(51) Int. Cl. H05K 7/20

(52) U.S. Cl. 165/104.33; 361/700; 165/80.3

(57) ABSTRACT

A compound heat-dissipating device is used to help a chip or a CPU to dissipate excessive heat. The compound heat-dissipating device has two heat sinks, two fans respectively arranged on the two heat sinks, and a heat pipe connected between the two heat sinks for increasing efficiency of heat dissipation.

### BACKGROUND OF THE INVENTION

1. Field of the Invention

The present invention relates to a compound heat-dissipating device, and especially to a compound heat-dissipating device used to dissipate effectively the high temperature from a chip or a CPU by two heat sinks and two fans.

2. Description of the Related

According to the development of computer industry, heat-generating sources such as a chip or a CPU have increasingly fast operation velocities, and relatively more and more heat is generated thereby. In order to dissipate the heat from a heat-generating source and maintain a normal operation temperature, the heat sink with a larger area is used on a heat surface of the heat-generating source for dissipating the heat.

Referring to FIG. 1, the prior art provides a heat sink 80, which is composed of a plurality of fins 81 made of good heat-conducting metal materials. Each of the fins 81 is thin and has a larger heat-dissipating surface. The heat sink 80 can be disposed on the heat-generating surface of a chip or a CPU for conducting the heat from the heat-generating source to the fins 81. Moreover, the prior art further provides a fan 90 arranged on the heat sink 80 for guiding and blowing cold air into the second heat sink 40 for conducting the heat from the second heat sink 40 to the exterior.

However, the heat sink of the prior art has a fan arranged on the heat sink, only, which makes the heat dissipation thereof suboptimal. If the heat-generating source, such as a chip or a CPU, generates an excessive amount of heat, the fan is not enough to dissipate the high heat. Moreover, the fan only can be used for a single heat-generating source (as CPU). Other heat-generating sources, such as a South Bridge, a North Bridge, a MOS or a RAM, dissipate heat by a system fan.

With the employment of unique considerations and application of theories, and based on several years experience in specialized production of all flexible assembly systems and mechanisms, the inventor has come up with an innovative a compound heat-dissipating device.

### SUMMARY OF THE INVENTION

The primary object of the present invention is to provide a compound heat-dissipating device, which includes two heat sinks and two fans for increasing the heat-dissipating efficiency for excessively high temperatures. Moreover, one heat sink and fan are assembled together for dissipating the heat from a chip or a CPU, and another heat sink and fan are assembled together for dissipating the heat from the motherboard.

In order to achieve the above objects, the present invention provides a compound heat-dissipating device comprising a first heat sink, a first fan, at least one heat pipe, a second heat sink and a second fan.

The first fan is disposed on the first heat sink. The at least one heat pipe has a first side and second side, and the first side is connected to the first heat sink. The second heat sink is connected to the second side of the at least one heat pipe. The second fan is disposed on the second heat sink.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawing, in which:

FIG. 1 is a schematic, perspective view of the heat-dissipating device of the prior art;

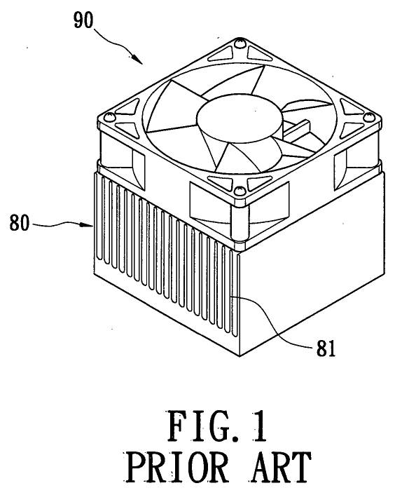

FIG. 2 is a schematic, exploded view of the compound heat-dissipating device of the present invention;

FIG. 3 is a schematic, cross-sectional view of the compound heat-dissipating device of the present invention;

FIG. 4 is another schematic, perspective view of the compound heat-dissipating device of the present invention;

FIG. 5 is schematic, side view of the compound heat-dissipating device of the present invention; and

FIG. 6 is a schematic view of the compound heat-dissipating device in use according to the present invention.

### DETAILED DESCRIPTION OF PREFERRED EMBODIMENTS

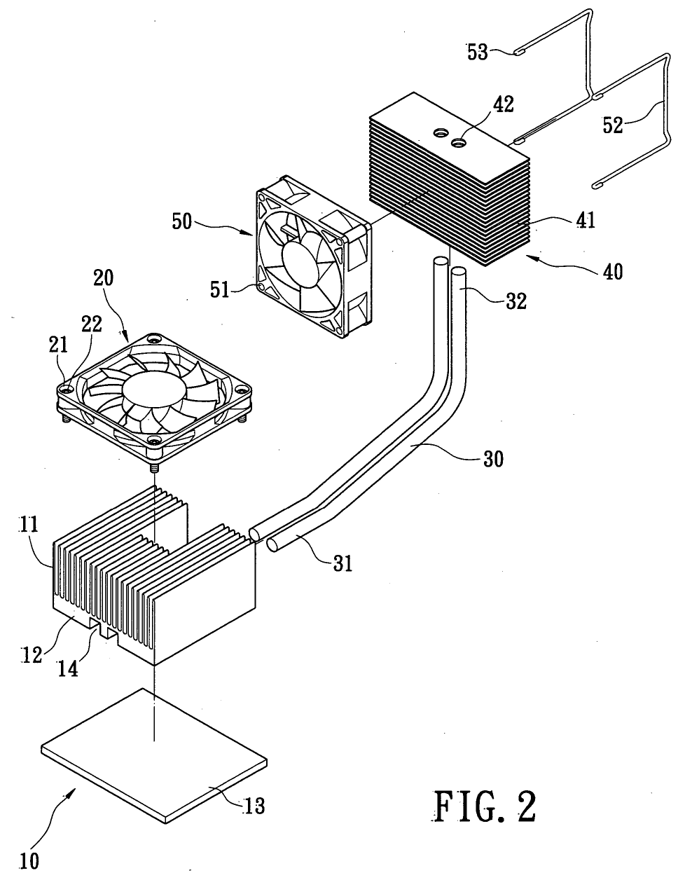

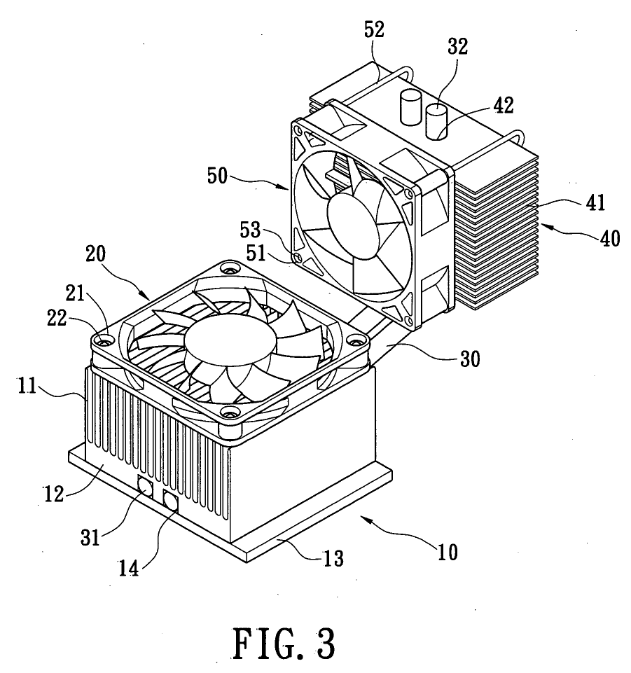

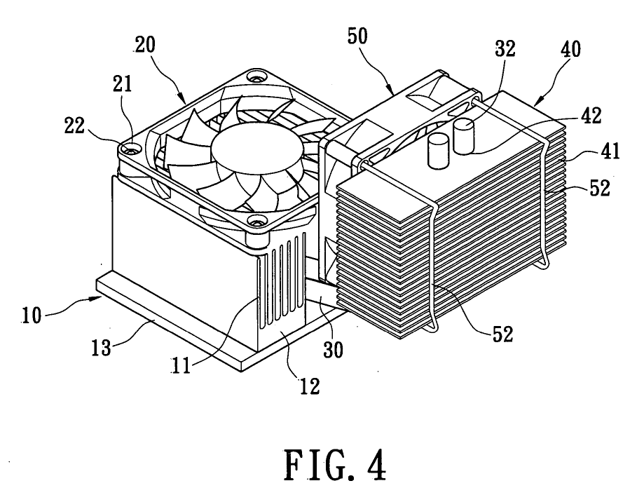

Referring to FIGS. 2 to 5, the present invention provides a compound heat-dissipating device, which comprises a first heat sink 10, a first fan 20, at least one heat pipe 30, a second heat sink 40 and a second fan 50.

The first heat sink 10 includes a plurality of first fins 11 and a base portion 12. The first fins 11 and the base portion 12 are made of good heat-conducting metal material like copper or aluminum. Each of the first fins 11 has a thin shape that has a larger heat-dissipating surface. The first fins 11 with a bottom side are integrally connected to the base portion 12. The first fins 11 and the base portion 12 are integrated with each other to form the whole first heat sink 10. The first heat sink 10 has a plurality of predetermined gaps between each two first fins 11 to form a plurality of passageways for air to pass therethrough. The first heat sink 10 further includes a heat-conducting plate 13 connected to the base portion 12. The heat-conducting plate 13 is made of a good heat-conducting metal material like copper or aluminum and can be disposed on a heat source of a CPU. The first heat sink 10 has at least one first through hole 14 formed in the base portion 12 for receiving at least one corresponding heat pipe 30.

The first fan 20 is disposed on the first fins 11 of the first heat sink 10 and may be a cross fan or any other type of fan. The first fan 20 has four first fixing holes 21 formed at four corners thereof, respectively. The first fan 20 is screwed and fixed on the first fins 11 of the first heat sink 10 by four first fixing elements penetrating through the corresponding four first fixing holes 21.

The heat pipe 30 has a predetermined length and can be bent according to a user's preferences. The present invention provides two heat pipes 30. Each of the heat pipes 30 has a first side 31 and a second side 32. The first side 31 is received in the first through hole 14 of the first heat sink 10 or connected to the first heat sink 10 by welding so as to fix the first side 31 on the first heat sink 10.

The second heat sink 40 includes a plurality of second fins 41. The second fins 41 are made of a good heat-conducting metal material like copper or aluminum. Each of the second fins 41 is thin and has a large heat-dissipating surface. The second heat sink 40 has a plurality of predetermined gaps between each two second fins 41 to form a plurality of passageways for air to pass therethrough. The second heat sink 40 has two second through holes 42 corresponding to the second sides 32 of the heat pipes 30. The second side 32 of the heat pipe 30 is disposed through the second through hole 42. The second side 32 of the heat pipe 30 is connected to the second heat sink 40 by welding so as to fix the second side 32 on the second heat sink 40.

The second fan 50 is arranged at one side of the second fins 41 of the second heat sink 40, and may be a cross fan or any type of fan. The second fan 50 has four second fixing holes 51 formed in four corners thereof, respectively. The second fan 50 further comprises two second fixing elements 52 disposed through the four second fixing holes 51. The second fixing element 52 is a U-shaped clamp. Each of the second fixing elements 52 has two large fixed sides 53 disposed at two sides thereof. The four fixed sides 53 are respectively clamped in the four second fixing holes 51 for clamping the two second fixing elements on an outside of the second fins 41 of the second heat sink 40, and fixing the second fan 50 on the second fins 41 of the second heat sink 40.

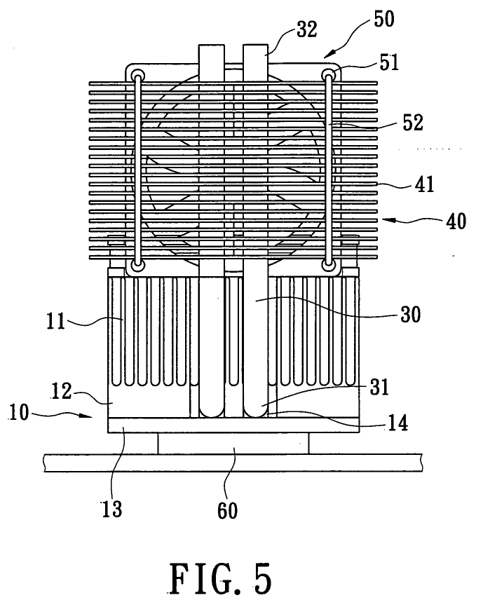

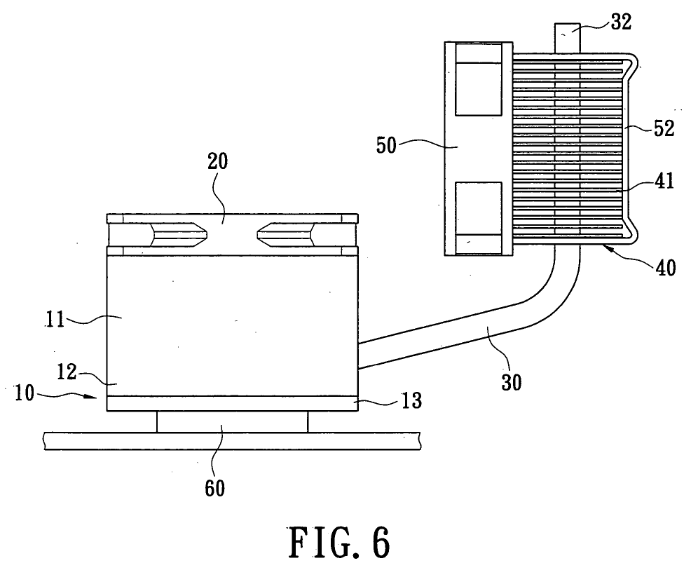

Referring to FIGS. 5 and 6, the first heat sink 10 can be disposed on a surface of a heat-generating source 60 by the heat-conducting plate 13 for conducting excessive heat from the heat-generating source 60 to the first fins 11 of the first heat sink 10 to help the heat-generating source 60 to dissipate the heat. The first fan 20 is used to guide and blow cold air into the first heat sink 10 for conducting the heat from the heat-generating source 60 to the exterior and reducing the working temperature in the heat-generating source 60.

The first heat sink 10 is connected to the second heat sink 40 and the second fan 50 by the heat pipe 30 for uniformly guiding the high temperature from the heat-generating source 60 and the first heat sink 10 to the second heat sink 40. The second fan 50 is used to guide and blow cold air into the second heat sink 40 for conducting the heat from the second heat sink 40 to the exterior.

Because the present invention provides the second heat sink 40 and the second fan 50, the sudden high temperature in the heat-generating source 60 will be effectively dissipated. Moreover, the present invention also can be used with other heat-generating sources, such as a South Bridge, a North Bridge, a MOS or a RAM, to dissipate the high temperature for increasing the heat-dissipating efficiency in a computer system.

Although the present invention has been described with reference to the preferred embodiment thereof, it will be understood that the invention is not limited to the details thereof. Various substitutions and modification have suggested in the foregoing description, and other will occur to those of ordinary skill in the art. Therefore, all such substitutions and modifications are intended to be embraced within the scope of the invention as defined in the appended claims.

What is claimed is:

1. A compound heat-dissipating device, comprising:
a first heat sink;
a first fan disposed on the first heat sink;
at least one heat pipe comprising a first side and second side, the first side connecting to the first heat sink;
a second heat sink connecting to the second side of the at least one heat pipe; and
a second fan disposed on the second heat sink.

2. The compound heat-dissipating device as claimed in claim 1, wherein the first heat sink includes at least one first through hole, and the first side of the heat pipe is received in the at least one first through hole.

3. The compound heat-dissipating device as claimed in claim 1, wherein the first fan is fixed on the first heat sink by a first fixing element.

4. The compound heat-dissipating device as claimed in claim 1, wherein the first side of the heat pipe is welded on the first heat sink.

5. The compound heat-dissipating device as claimed in claim 1, wherein the second side of the heat pipe is welded on the second heat sink.

6. The compound heat-dissipating device as claimed in claim 1, wherein the second fan is fixed on the second heat sink by a second fixing element.

7. The compound heat-dissipating device as claimed in claim 6, wherein the second fan has four second fixing holes formed in four corners thereof and the second fixing element is a clamp, the second fixing element having four sides respectively disposed through the four second fixing holes, and clamping on an outside of the second heat sink.
